(19) United States
(12) Patent Application Publication
(10) Pub. No.: US 2012/0031484 A1
(43) Pub. Date: Feb. 9, 2012

(54) CONDUCTIVE PASTE FOR A SOLAR CELL ELECTRODE

(75) Inventors: Hisashi Matsuno, Tokyo (JP); Norihiko Takeda, Kanagawa (JP)

(73) Assignee: E. I. DU PONT DE NEMOURS AND COMPANY, Wilmington, DE (US)

(21) Appl. No.: 13/204,027

(22) Filed: Aug. 5, 2011

Related U.S. Application Data
(60) Provisional application No. 61/371,324, filed on Aug. 6, 2010.

(51) Int. Cl. H01L 31/0224; H01L 31/18; H01B 1/24

(52) U.S. Cl. 136/256; 252/519.33; 438/98; 257/E31.124

(57) ABSTRACT

The invention relates to a method of manufacturing a solar cell electrode comprising steps of: (a) preparing a semiconductor substrate comprising a negative layer, a positive layer and passivation layers formed on the negative layer and the positive layer; (b) applying a conductive paste onto the passivation layer(s) formed on the positive layer, on the negative layer, or on both of the positive layer and the negative layer, wherein the conductive paste comprises; (i) a conductive powder; (ii) a glass frit comprising 45 to 81 mole percent (mol %) of PbO, 1 to 38 mol % of SiO₂ and 5 to 47 mol % of B₂O₃, based on the total molar fraction of each component in the glass frit; and (iii) a resin binder; and (c) firing the conductive paste.

### FIELD OF THE INVENTION

This invention relates to a solar cell, more specifically a solar cell electrode and a method of manufacturing a solar cell electrode.

### TECHNICAL BACKGROUND OF THE INVENTION

An electrode for a solar cell, in general, requires low electrical resistance to facilitate electrical property of a solar cell.

US 2006/0102228 discloses a solar cell contact made from a mixture wherein the mixture comprises a solids portion and an organic portion, wherein the solids portion comprises from about 85 to about 99 wt % of silver, and from about 1 to about 15 wt % of a glass component wherein the glass component comprises from about 15 to about 75 mol % of PbO, from about 5 to about 50 mol % of SiO₂, and preferably with no B₂O₃.

### SUMMARY OF THE INVENTION

An objective of the present invention is to provide a conductive paste that can render a solar cell electrode good electrical property and to provide a solar cell that has an electrode formed from the conductive paste.

An aspect of the invention relates to a method of manufacturing a solar cell electrode comprising steps of: (a) preparing a semiconductor substrate comprising a negative layer, a positive layer and passivation layers formed on the negative layer and the positive layer; (b) applying a conductive paste onto the passivation layer(s) formed on the positive layer, on the negative layer, or on both of the positive layer and the negative layer, wherein the conductive paste comprises; (i) a conductive powder; (ii) a glass frit comprising 45 to 81 mole percent (mol %) of PbO, 1 to 38 mol % of SiO₂ and 5 to 47 mol % of B₂O₃, based on the total molar fraction of each component in the glass frit; and (iii) a resin binder; and (c) firing the conductive paste.

Another aspect of the invention relates to a conductive paste for manufacturing a solar cell electrode comprising: a conductive powder; a glass frit comprising, 45 to 81 mole percent (mol %) of PbO, 1 to 38 mol % of SiO₂ and 5 to 47 mol % of B₂O₃, based on the total molar fraction of each component in the glass frit; and a resin binder.

A solar cell electrode by the present invention obtains superior electrical characteristics.

### BRIEF DESCRIPTION OF THE DRAWINGS

FIG. 1 is a schematic diagram illustrating a method of manufacturing an N-type base solar cell.

FIG. 2 is a schematic diagram illustrating a method of manufacturing a back contact type solar cell.

### DETAILED DESCRIPTION OF THE INVENTION

A conductive paste for a solar cell electrode comprises a conductive powder, a glass frit, and a resin binder. The conductive paste is described below as well as a method of manufacturing a solar cell electrode made of the conductive paste.

### Conducting Powder

The conductive powder is a metal or alloy powder forming a conductive layer to transport electrons in an electrode. The electrical conductivity of the conductive powder is more than 1.00×10⁷ Siemens (S)/m at 293 Kelvin in an embodiment, more than 3.00×10⁷ S/m at 293 Kelvin in another embodiment, and more than 5.00×10⁷ S/m at 293 Kelvin in another embodiment.

The conductive metal has electrical conductivity of 1.00×10⁷ Siemens (S)/m or more at 293 Kelvin in an embodiment. Such conductive metal is, for example, iron (Fe; 1.00×10⁷ S/m), aluminum (Al; 3.64×10⁷ S/m), nickel (Ni; 1.45×10⁷ S/m), copper (Cu; 5.81×10⁷ S/m), silver (Ag; 6.17×10⁷ S/m), gold (Au; 4.17×10⁷ S/m), molybdenum (Mo; 2.10×10⁷ S/m), magnesium (Mg; 2.30×107 S/m), tungsten (VV; 1.82×10⁷ S/m), cobalt (Co; 1.46×10⁷ S/m) and zinc (Zn; 1.64×10⁷ S/m).

The conductive powder can comprise a metal selected from a group consisting of Fe, Al, Ni, Cu, Ag, Au, Mo, Mg, W, Co and Zn and a mixture thereof in an embodiment. The conductive powder can comprise a metal selected from a group consisting of Al, Ni, Cu, Ag, Au, W and a mixture thereof in another embodiment. The conductive powder can comprise a metal selected from a group consisting of Ag, Al, Cu, Ni and a mixture thereof in another embodiment. These metals are relatively easy to purchase in a market.

The conductive powder can comprise Ag and Al in another embodiment. A solar cell electrode comprising Ag and Al can have a lower resistance as shown in Example below.

The conductive powder can be an alloy powder. The alloy includes, but not limited to, Ag—Al, Ag—Cu, Ag—Ni, and Ag—Cu—Ni.

There is no special restriction on particle diameter of the conductive powder. However, the particle diameter can affect a sintering characteristic of the conductive powder. For example, large silver particles are sintered more slowly than silver particles of small particle diameter.

Particle diameter can be 0.1 to 10 μm in an embodiment, 1 to 8 μm in another embodiment, and 2 to 5 μm in another embodiment,

The particle diameter (D50) is obtained by measuring the distribution of the particle diameters by using a laser diffraction scattering method and can be defined as D50. Microtrac model X-100 is an example of the commercially-available devices.

The conductive powder can be nodular, flaky or spherical in shape. The nodular powder is irregular particles with knotted or rounded shapes.

The conductive powder can comprise two or more types of conductive powder of different diameters, or different shape.

The conductive powder can be 60 to 90 weight percent (wt %) in an embodiment, 70 to 88 wt % in another embodiment, 78 to 85 wt % in another embodiment, based on the total weight of the conductive paste. The conductive powder with such amount in a conductive paste can retain sufficient conductivity.

The conductive powder can be of ordinary high purity (99%) in an embodiment. However, depending on electrical requirements of the electrode pattern, less pure metal or alloy can also be used. The purity of the conductive powder is more than 95% in an embodiment, and more than 90% in another embodiment.

The conductive powder can contain two or more different metals or alloys. The conductive powder can comprise Al powder in an embodiment. By comprising the Al powder, an electrical property of a solar cell can be improved as shown in Example below. Basically, the Al powder conditions such as particle size can be the same as the conductive powder explanation above. However, the following condition can be taken into consideration when the Al powder is used with the other metal powder or the alloy powder as a mixture or an alloy powder.

Al powder can be 0.1 to 8 weight percent (wt %) in an embodiment, 0.3 to 6 wt % in another embodiment, and 0.5 to 4 wt % in another embodiment, based on the weight of the conductive powder.

Particle diameter (D50) of the Al aluminum powder or Al containing alloy powder can be not smaller than 1 μm in an embodiment, not smaller than 2.0 μm in another embodiment, and not smaller than 3.0 μm in another embodiment. The particle diameter (D50) of the Al powder or Al containing alloy powder is not larger than 20 μm in an embodiment, not larger than 12 μm in another embodiment, and not larger than 8 μm in another embodiment. With such particle diameter of the aluminum powder, the electrode can have better contact with a semiconductor layer.

To measure the particle diameter (D50) of the Al powder, the same method as used for the conductive powder can be applied.

The purity of the Al powder or Al containing alloy powder can be 99% or higher. The purity of the Al powder or Al containing alloy powder can be more than 95% in an embodiment, and more than 90% in another embodiment.

### Glass Frit

Glass frits used in the pastes described herein promote sintering of the conductive powder and also to facilitate binding of the electrode to the substrate.

Glass compositions, also termed glass frits, are described herein as including percentages of certain components (also termed the elemental constituency). Specifically, the percentages are a relative amount of a glass starting material that is subsequently processed as described herein to form a glass composition. Such nomenclature is conventional to one of skill in the art. In other words, the glass composition contains certain components, and the percentages of those components are expressed as a percentage of the corresponding oxide form. As recognized by one of skill in the art in glass chemistry, a certain portion of volatile species can be released during the process of making the glass. An example of a volatile species is oxygen.

If starting with a fired glass, one of skill in the art may calculate the percentages of starting components described herein (elemental constituency) using methods known to one of skill in the art including, but not limited to: Inductively Coupled Plasma-Emission Spectroscopy (ICP-ES), Inductively Coupled Plasma-Atomic Emission Spectroscopy (ICP-AES), Inductively Coupled Plasma-Mass Spectrometry (ICP-MS) and X-Ray Fluorescence spectroscopy (XRF).

The glass frit comprises 45 to 81 mole percent (mol %) of PbO, 1 to 38 mol % of SiO₂ and 5 to 47 mol % of B₂O₃, based on the total molar fraction of each component in the glass frit.

The glass frit compositions described herein, including those listed in Table I, are not limiting to onws with the exemplified components. It is contemplated that one of ordinary skill in the art of glass chemistry could make minor substitutions of additional ingredients and not substantially change the desired properties of the glass composition. For example, substitutions of glass formers such as P₂O₅ 0-3, GeO₂ 0-3, V₂O₅ 0-3 in mol % can be used either individually or in combination to achieve similar performance for PbO, SiO₂ or B₂O₃. For example, one or more intermediate oxides, such as TiO₂, Ta₂O₅, Nb₂O₅, ZrO₂, CeO₂, and SnO₂ can be added to the glass composition.

PbO in the glass frit can be 45 to 81 mol % in an embodiment, 48 to 75 mol % in another embodiment, 50 to 65 mol % in another embodiment, based on the total molar fraction of each component in the glass frit.

SiO₂ in the glass frit can be 1 to 38 mol % in an embodiment, 1 to 32 mol % in another embodiment, 1.5 to 25 mol % in another embodiment, based on the total molar fraction of each component in the glass frit.

B₂O₃ in the glass frit can be 5 to 47 mol % in an embodiment, 10 to 40 mol % in another embodiment, 20 to 38 mol % in another embodiment, based on the total molar fraction of each component in the glass frit.

The glass frit can further comprise 0 to 10 mole percent (mol %) of alumina (Al₂O₃) in an embodiment, 0.1 to 8.2 mol % in another embodiment, 0.5 to 5 mol % in another embodiment, 0.5 to 3 mol % in another embodiment, 1 to 3 mol % in another embodiment, based on the total molar fraction of each component in the glass frit.

The glass compositions used herein, in molar percent total glass composition, are shown in Table 1. Unless stated otherwise, as used herein, mol % means mol % of glass composition only. Specimens of PbO containing glasses are shown in Table 1.

TABLE 1
(mol %)

| # | PbO | SiO2 | Al₂O₃ | B₂O₃ | Total |
|---|---|---|---|---|---|
| 1 | 50.01 | 21.96 | 1.99 | 26.04 | 100 |
| 2 | 50.01 | 11.96 | 1.99 | 36.04 | 100 |
| 3 | 50.01 | 31.96 | 1.99 | 16.04 | 100 |
| 4 | 50.01 | 41.96 | 1.99 | 6.04 | 100 |
| 5 | 40.01 | 21.96 | 1.99 | 36.04 | 100 |
| 6 | 60.01 | 21.96 | 1.99 | 16.04 | 100 |
| 7 | 70.01 | 21.96 | 1.99 | 6.04 | 100 |
| 8 | 45.01 | 16.96 | 1.99 | 36.04 | 100 |
| 9 | 55.01 | 26.96 | 1.99 | 16.04 | 100 |
| 10 | 60.01 | 31.96 | 1.99 | 6.04 | 100 |
| 11 | 60.01 | 11.96 | 1.99 | 26.04 | 100 |
| 12 | 40.01 | 31.96 | 1.99 | 26.04 | 100 |
| 13 | 40.01 | 11.96 | 1.99 | 46.04 | 100 |
| 14 | 70.01 | 11.96 | 1.99 | 16.04 | 100 |
| 15 | 40.01 | 41.96 | 1.99 | 16.04 | 100 |
| 16 | 50.01 | 1.96 | 1.99 | 46.04 | 100 |
| 17 | 60.01 | 1.96 | 1.99 | 36.04 | 100 |
| 18 | 70.01 | 1.96 | 1.99 | 26.04 | 100 |
| 19 | 80.01 | 1.96 | 1.99 | 16.04 | 100 |
| 20 | 60.01 | 12.96 | 0.00 | 27.03 | 100 |
| 21 | 60.01 | 12.46 | 1.00 | 26.53 | 100 |
| 22 | 60.01 | 10.96 | 4.00 | 25.03 | 100 |
| 23 | 60.01 | 8.96 | 8.00 | 23.03 | 100 |

The glass frit can have a softening point in a range of 250 to 650° C. in an embodiment, 300 to 500° C. in another embodiment, 300 to 450° C. in another embodiment, and 310 to 400° C. in another embodiment. In this specification, “softening point” is determined by differential thermal analysis (DTA). To determine the glass softening point by DTA, sample glass is ground and is introduced with a reference material into a furnace to be heated at a constant rate of 5 to 20° C. per minute. The difference in temperature between the two is detected to investigate the evolution and absorption of heat from the material. In general, the first evolution peak is on glass transition temperature (Tg), the second evolution peak is on glass softening point (Ts), the third evolution peak is on crystallization point. When a glass frit is a noncrystalline glass, the crystallization point would not appear in DTA.

The glass frit can be a noncrystalline glass upon firing at 0 to 800° C. in an embodiment. In this specification, “noncrystalline glass” is determined by DTA as described above. The third evolution peak would not appear upon firing at 0 to 800° C. in a noncrystalline glass DTA.

The glass frit can be 2 to 21 parts by weight in an embodiment, 4 to 16 parts by weight in another embodiment, 6 to 13 parts by weight in another embodiment, based on the 100 parts by weight of the conductive powder. The glass frit with such amount can contribute to metal sintering during firing or electrode adhesion to the substrate.

The glass frits described herein can be manufactured by a conventional glass making technique. The following procedure is one example. Ingredients are weighed then mixed in the desired proportions and heated in a furnace to form a melt in platinum alloy crucibles. As well known in the art, heating is conducted to a peak temperature (800-1400° C.) and for a time such that the melt becomes entirely liquid and homogeneous. The molten glass is then quenched between counter rotating stainless steel rollers to form a 10-15 mil thick platelet of glass. The resulting glass platelet is then milled to form a powder with its 50% volume distribution set between to a desired target (e.g. 0.8-1.5 μm). One skilled the art of producing glass frit may employ alternative synthesis techniques such as but not limited to water quenching, sol-gel, spray pyrolysis, or others appropriate for making powder forms of glass. US patent application numbers US 2006/231803 and US 2006/231800, which disclose a method of manufacturing a glass useful in the manufacture of the glass frits described herein, are hereby incorporated by reference herein in their entireties.

One of skill in the art would recognize that the choice of raw materials could unintentionally include impurities that can be incorporated into the glass during processing. For example, the impurities can be present in the range of hundreds to thousands ppm.

The presence of the impurities would not alter the properties of the glass, the thick film composition, or the fired device. For example, a solar cell containing the thick film composition can have the efficiency described herein, even if the thick film composition includes impurities.

### Metal Additive

The thick film composition can comprise a metal additive in an embodiment. The metal additive can be selected from one or more of the following: (a) a metal wherein said metal is selected from Pb, Bi, Gd, Ce, Zr, Ti, Mn, Sn, Ru, Fe, B, Ga, In, TI, Si and Cr; (b) a metal oxide of one or more of the metals selected from Zn, Pb, Bi, Gd, Ce, Zr, Ti, Mn, Sn, Ru, Co, Fe, Cu, B, Al, Ga, In, TI, Si and Cr; (c) any compounds that can generate the metal oxides of (b) upon firing; and (d) mixtures thereof in another embodiment.

The additive can comprise a Zn-containing additive in another embodiment. The Zn-containing additive can include one or more of the following: (a) Zn, (b) metal oxides of Zn, (c) any compounds that can generate metal oxides of Zn upon firing, and (d) mixtures thereof. The Zn-containing additive may include Zn resinate in another embodiment.

The metal additive in the conductive paste can be 2 to 10 parts by weight, based on 100 parts by weight of the conducting powder in an embodiment.

Particle diameter (D50) can be 7 nanometers (nm) to 125 nm in an embodiment.

### Resin Binder

The conductive paste contains a resin binder. The conductive powder and the glass frit is dispersed in the resin binder, for example, by mechanical mixing to form viscous compositions called “pastes”, having suitable consistency and rheology for printing. A wide variety of inert viscous materials can be used as a resin binder.

In the present specifications document, the “resin binder” contains a polymer as resin. If viscosity is high, solvent can be added to the resin binder to adjust the viscosity.

Any resin binder can be used, for example, a pine oil solution, an ethylene glycol monobutyl ether monoacetate solution, terpineol solution, or texanol solution of a resin or ethyl cellulose. In another embodiment, the resin binder can be a texanol solution of ethyl cellulose.

A solvent containing no polymer, for example, water or an organic liquid can be used as a viscosity-adjusting agent.

The resin binder can be 4 to 17 parts by weight, based on 100 parts by weight of the conducting powder in an embodiment.

### Additives

Thickener, stabilizer or surfactant as additives may be added to the conductive paste of the present invention. Other common additives such as a dispersant, viscosity-adjusting agent, and so on can also be added. The amount of the additive depends on the desired characteristics of the resulting electrically conducting paste and can be chosen by people in the industry. The additives can also be added in multiple types.

### Manufacturing Solar Cell Electrode

The present invention can be applicable to any type of a solar cell using a semiconductor substrate comprising a negative layer, a positive layer and passivation layers formed on the negative layer and the positive layer.

The positive layer can be defined as a semiconductor layer containing an impurity called acceptor dopant where the acceptor dopant introduces deficiency of valence electrons in the semiconductor element. In the positive layer, the acceptor dopant takes in free electrons from semiconductor element and consequently positively charged holes are generated in the valence band.

The negative layer can be defined as a semiconductor layer containing an impurity called donor dopant where the donor dopant introduces extra valence electrons in the semiconductor element. In the negative layer, free electrons are generated from the donor dopant in the conduction band.

By adding an impurity to an intrinsic semiconductor as above, electrical conductivity can be varied not only by the number of impurity atoms but also, by the type of impurity atom and the changes can be a thousand fold and a million fold.

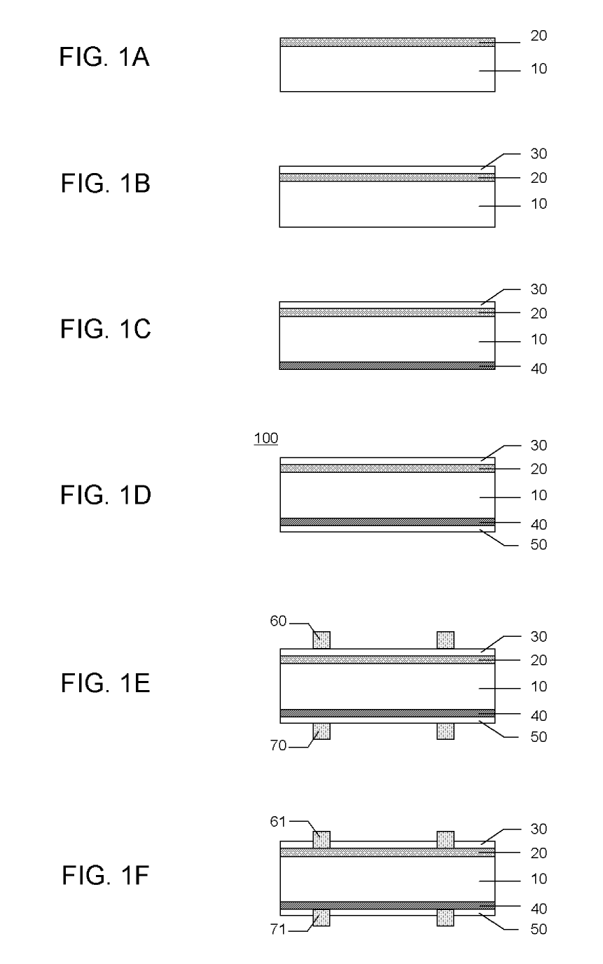

Embodiments of the present invention are explained below with reference to the drawings through FIG. 1 to FIG. 5. The embodiments given below are only examples, and appropriate design changes are possible for those skilled in the art.

FIG. 1 illustrates a method of manufacturing an N-type base solar cell. In N-type base solar cell, a semiconductor substrate is an N-type base semiconductor substrate comprising a negative layer, a positive layer and passivation layers formed on the negative layer and the positive layer, wherein the positive layer is formed on one side of the negative layer.

In FIG. 1A, a part of an N-type base semiconductor substrate comprising a negative layer 10 and a positive layer 20 is prepared. The positive layer 20 can be formed on one side of the negative layer 10. The positive layer 20 can be formed by doping with an acceptor impurity, for example by thermal diffusion of boron tribromide (BBr₃) into one side of surface of the negative layer.

The N-type base semiconductor substrate can be a silicon substrate. The semiconductor substrate can have sheet resistance on the order of several tens of ohms per square (ohm/□).

In FIG. 1B, a passivation layer 30 is formed on the one side of the positive layer 20. With the passivation layer, the semiconductor substrate can reduce loss of incident light and/or to reduce loss of charge carriers by recombination of electrons and positive holes at the surface of a substrate. The passivation layer 30 can be also called anti-reflection coating (ARC) when the passivation layer works to reduce loss of incident light. Silicon nitride (SiNₓ), titanium oxide (TiO₂), aluminium oxide (Al₂O₃), silicon oxide (SiOₓ), tantalum oxide (Ta₂O₅), indium tin Oxide (ITO), or silicon carbide (SiCₓ) can be used as a material for forming a passivation layer. The passivation layer in the N-type base solar cell can be formed fron SiO₂, Al₂O₃, SiNₓ in an embodiment, Al₂O₃ in another embodiment. These material can be effective for suppressing recombination of electrons and positive holes at the surface of the positive layer.

Al₂O₃ layer or TiO₂ layer can be formed by atomic layer deposition (ALD) method. TiO₂ layer can be formed by a thermal chemical vapor deposition (CVD) method with an organic titanate and water heated at 250° C. to 300° C.

SiOₓ layer can be formed by thermal oxidation method, thermal CVD method or plasma-enhanced CVD method. In case of thermal CVD method, Si₂Cl₄ gas and O₂ gas are used to be heated at from 700° C. to 900° C. In case of plasma-enhanced CVD method, SiH₄ gas and O₂ gas, for example, are used to be heated at from 200° C. to 700° C. SiOₓ layer can be also formed by wet oxidation method with nitric acid (HNO₃).

The passivation layer can be a multiple stack of materials. For example, the passivation layer 30 can consist of two layers which are Al₂O₃ layer formed on the positive layer 20, and SiNₓ layer formed on the Al₂O₃ layer.

Although it depends on a requirement on a solar cell, the passivation layer 30 thickness can be 1 to 2000 angstrom thick.

As illustrated in FIG. 1C, an n⁺-layer 40 can be formed at the other side of the positive layer 20 in the negative layer 10 in an embodiment, although it is not essential. The n⁺-layer 40 can be omitted. The n⁺-layer 40 contains a donor impurity with higher concentration than that in the negative layer 10. For example, the n⁺-layer 40 can be formed by thermal diffusion of phosphorus in the case of silicon semiconductor. By forming n⁺-layer 40, the recombination of electrons and holes at the border of negative layer 10 and n⁺-layer 40 can be reduced. When the n⁺-layer 40 is formed, the N-type base semiconductor substrate comprises the n⁺-layer between the negative layer 10 and a passivation layer 50 which is formed in the following step.

In FIG. 1D, another passivation layer 50 is formed on the n⁺-layer 40.

When the n⁺-layer 40 is not formed, the passivation layer 50 can be formed directly formed on the negative layer. The passivation layer 50 can be formed as described above for the passivation layer 30. The passivation layer 50 can be different from the one on the positive layer in terms of its forming material and thickness or forming method. Here, the N-type base semiconductor substrate 100 comprising at least the negative layer 10, the positive layer 20 and the passivation layers thereon is prepared to form a solar cell electrode.

In FIG. 1E, the conductive paste 60 is applied onto the passivation layer 30 on the positive layer, and successively dried. The conductive paste 60 can be applied by screen printing.

The pattern of the applied conductive paste is, in an embodiment, comb-shaped with plural parallel lines called finger line or grid line and bus-bar vertically crossing to the finger lines, which is general and well known in the field of solar cell.

The conductive paste 70 is applied onto the passivation layer 50 on the n⁺-layer 40, and successively dried. The conductive paste 70 can be applied by screen printing. The conductive paste 70 can be same as the one applied on the side of the positive layer or different from it.

It is described here as an example that conductive paste is applied on the side of the positive layer first. However, it is also possible to apply the conductive paste 70 on the side of the negative layer first and then apply to the other side. Even it is possible to apply to the front and the back at the same time.

The conductive paste can be applied only onto the passivation layer 30 on the positive layer 20 in an embodiment. The conductive paste can be used on both passivation layers, however, at least when applied on the side of the positive layer, a solar cell electrode can be superior on an electrical resistance as shown in Table 2 in Example below.

The conductive paste can be applied onto both of the passivation layer 30, 50 in an embodiment. As shown in Example, applying the conductive paste on both sides, an electrical property of a solar cell can be almost equal to the case of applying only on the side of the positive layer.

Firing is then carried out in an infrared furnace at a measured temperature, for example, from 450° C. to 1000° C. Firing total time can be from 30 seconds to 5 minutes. At firing measured temperature of over 1000° C. or at a firing time of more than 5 minutes damage could occur to a semiconductor substrate.

Firing profile can be 10 to 60 seconds at over 400° C., and 2 to 10 seconds at over 600° C. of measured temperature in another embodiment. Firing peak temperature can be lower than 800° C. When the firing temperature and time within the above-mentioned range are used, less damage can occur to a semiconductor substrate during firing. The firing temperature can be measured with a thermocouple attached to the upper surface of the silicon substrate.

As illustrated in FIG. 1F, the conductive pastes 60 and 70 fire through the passivation layers 30 and 50 respectively during the firing so that a p-type solar cell electrode 61 and an n-type solar cell electrode 71 can be formed with a sufficient electrical property.

The soar cell electrode in the present invention can be at least the p-type electrode 61 formed on the positive layer 20 in an embodiment. The soar cell electrode can be both of the p-type electrode 61 and the n-type electrode 71 in another embodiment.

When actually operated, the solar cell can be installed with the positive layer located at the front side which is light receiving side, and the negative layer located at the backside which is the opposite side of the light receiving side of a solar cell. The solar cell can be also installed the other way around so that the positive layer locates at the backside and the negative layer locates at the light receiving side. The light receiving side can be called a front side and the opposite side of the light receiving side can be called a back side. For a manufacturing of N-type base solar cell, the followings can be herein incorporated by reference.
A. Weeber et al. Status of N-type Solar Cells for Low-Cost Industrial Production; Proceedings of 24th European Photovoltaic solar Energy Conference and Exhibition, 21-25 September 2009, Hamburg, Germany
J. E. Cotter et al., P-Type versus n-Type Silicon Wafers: Prospects for High-Efficiency Commercial Silicon Solar Cells; IEEE transactions on electron devices; VOL. 53, NO. 8, August 2006, pp 1893-1896.

The solar cell electrode can be used in a back contact type of a solar cell in an embodiment. For the embodiment of the back contact type of solar cell, the followings explain a manufacturing process of a solar cell electrode formed in the back contact type solar cell.

The semiconductor substrate of the back contact type solar cell comprises a negative layer, a positive layer and passivation layers formed on the negative layer and the positive layer, wherein both of the negative layer and the positive layer locate on one side of the semiconductor substrate. The side where the positive layer and the negative layer exist comes to the back side that is the opposite side of a light receiving side when the solar cell installed in actual use under sunlight.

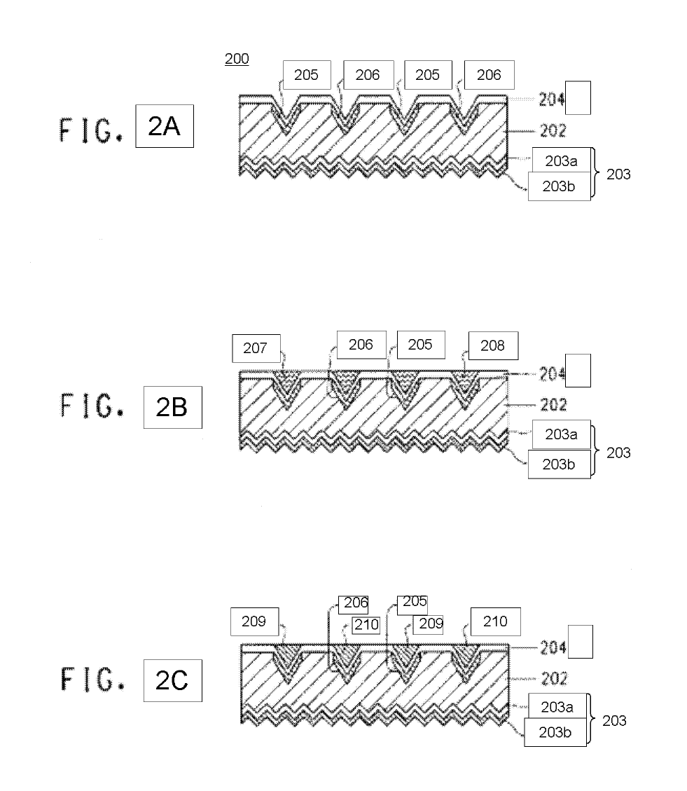

An explanation is provided for a method of manufacturing a solar cell electrode of the back contact type solar cell as well as a back contact type solar cell with reference to through FIG. 2.

A semiconductor substrate 200 comprising a semiconductor base 202, a negative layer 205, a positive layer 206 and passivation layer 204 formed on the negative layer 205 and the positive layer 206, wherein both of the negative layer 205 and the positive layer 206 locate on one side of the semiconductor substrate 200 is prepared as shown in FIG. 2A. The negative layer 205 and the positive layer 206 are formed on the surface of V grooves that were previously formed by etching with hydroxide (KOH) or tetramethyl ammonium hydroxide (TMAH).

The passivation layer 204 formed on the negative layer 205 and the positive layer 206 works to reduce loss of charge carriers by recombination of electrons and positive holes. The forming material and method of the passivation layers can be the same as described above.

The passivation layer 203 can be formed on the other side of the semiconductor base 202 in an embodiment, although it is optional. The passivation layer 203 locates to the light receiving side when the solar cell actually runs so that it can work to reduce loss of incident light in addition to reducing loss of charge carriers. The forming material and method of the passivation layer 203 can be also the same as described above. However an example of the passivation layer 203 is a two layer structure with silicon nitride (SiNₓ) layer 203 a and titanium dioxide (TiO₂) layer 203b. The two layer structure could have high refractive index.

Solar cell electrodes are formed using the conductive paste. The V grooves are applied with the conductive paste 207 and 208 as illustrated in FIG. 2B. Applying the conductive paste 207 and 208 can be carried out by a patterning method such as screen printing, stencil printing or dispenser applying. The V grooves can be filled with the conductive paste.

Next, the semiconductor substrate 200 in which the conductive paste 207 and 208 were applied is fired. The firing condition can be the same as N-type base solar cell described above. Through firing step, an n-type solar cell electrode 209 and a p-type solar cell electrode 210 are formed.

The conductive paste in the present invention as described above can be applied at least on the positive layer 206 in the back contact type solar cell in an embodiment. The conductive paste in the present invention as described above can be applied on both of the negative layer 205 and the positive layer 206 in another embodiment.

The conductive paste 207 and 208 can fire through the passivation layer 204 during firing, which is not shown in FIG. 2, so that the n-type solar cell electrode 209 and the p-type solar cell electrode 210 can reach to the negative layer 205 and the positive layer 206 respectively to form electrical contact between them.

Besides above explanation, US 2008/0230119 can be herein incorporated by reference.

### EXAMPLES

### Glass Property Measurement

The present invention is illustrated by, but is not limited to, the following examples.

### Preparation of Conductive Paste

Conductive pastes were prepared with the following procedure by using the following materials.
Conductive powder: 100 parts by weight of a mixture of silver (Ag) powder and aluminum (Al) powder was used.

Ag powder: Ag powder was 97.8 wt % of the conductive powder. The shape was spherical and particle diameter (D50) was 3.3 μm as determined with a laser scattering-type particle size distribution measuring apparatus.

Al powder: Al powder was 2.2 wt % of the conductive powder. The shape was spherical and particle diameter (D50) was 3.1 μm as determined with a laser scattering-type particle size distribution measuring apparatus.
Glass frit: 8.7 parts by weight of a glass frit with particle diameter (D50) of 2.0 μm was used. The glass frit compositions were illustrated in Table 2.
Resin binder: 14.4 parts by weight of a texanol solution of ethyl cellulose was used.
Additive: 0.4 parts by weight a viscosity modifier was used.

### Paste Preparation

Resin binder and the viscosity modifier were mixed for 15 minutes. To enable dispersion of a small amount of Al powder evenly in a conductive paste, Ag powder and Al powder were dispersed in the resin binder separately to mix together afterward.

First, Al powder was dispersed in some of the resin binder and mixed for 15 minutes to form Al slurry. Second, the glass frit was dispersed in the rest of the resin binder and mixed for 15 minutes and then Ag powder was incrementally added to form Ag paste. Then, the Al slurry and the Ag paste were separately and repeatedly passed through a 3-roll mill at progressively increasing pressures from 0 to 400 psi. The gap of the rolls was adjusted to 1 mil.

Then the Ag paste and the Al slurry were mixed together to form a conductive paste.

The viscosity as measured at 10 rpm and 25° C. with a Brookfield HBT viscometer with #14 spindle was 260 Pa·s. The degree of dispersion as measured by fineness of grind was 20/10 or less.

### Manufacture of A Solar Cell

N-type base silicon substrate with size of 30 mm×30 mm square that comprises a negative layer as a base, a positive layer and silicon nitride passivation layers formed thereon was prepared. The negative layer was a phosphorus doped silicon wafer. The positive layer was formed on one side of the silicon wafer by boron diffusion to have average sheet resistance of 60 Ω/□. The passivation layer on the positive layer was 90 nm thickness. The other side of the positive layer, the surface of the negative layer was doped with additional phosphorus to form n⁺-layer and then coated with silicon nitride passivation layer with 70 nm thickness.

A commercially available silver paste was screen printed onto the passivation layer formed on the n⁺-layer with a pattern consisted of fifteen finger lines with 200 μm wide, 27 mm long, 35 μm thick and a bus bar with 1.5 mm wide, 28.35 mm long, 22 μm thick. The finger lines were formed at one side of the bus bar, as it is called a comb shape. The printed silver paste was dried at 150° C. for 5 min in a convection oven.

The conductive paste obtained above was screen printed onto the passivation layer formed on the positive layer. The printed pattern was also a comb shape with fourteen parallel finger lines formed at one side of a bus-bar vertically crossing to the finger lines. The finger lines were 100 μm wide, 27 mm long, 20 μm thick, and a bus bar with 1.5 mm wide, 28.35 mm long, 20 μm thick. Intervals of the finger lines were 2.15 mm. The printed conductive paste was dried at 150° C. for 5 min in a convection oven.

The dried conductive pastes were then fired with the positive layer facing upward in an IR heating type of belt furnace (CF-7210, Despatch industry). The conductive pastes were fired at peak temperature setting at 825, 845, 865 and 885° C. separately that corresponded to measured peak temperature of 710, 730, 740 and 770° C., respectively. The firing time from furnace entrance to exit was 80 seconds. The temperature profile was measured with a thermocouple attached to the upper surface of the silicon substrate. The firing profile with measured temperature was over 400° C. for 22 seconds, over 600° C. for 6 seconds including the peak temperatures. The belt speed of the furnace was set to 550 cpm. A solar cell electrode was formed after the firing process.

### Test Procedure

The solar cells obtained above were tested with a commercially available IV tester (NCT-150AA, NPC Corporation) to obtain fill factor (FF). The Xe Arc lamp with an appropriate filter in the IV tester simulated the sunlight with air mass value of 1.5 with a known intensity and spectrum. The temperature of stage was regulated at fixed temperature of 25° C. The tester utilized a “four-point probe method” to measure current (I) with varying bias voltages (V) at approximately 300 load resistance settings to record the cell's I-V curve under photo-irradiation. The bus bar on the positive layer was connected to the multiple probes of the IV tester and the electrical signals were transmitted through the probes to a computer for calculating I-V parameters. FF values were obtained with a standard method of finding a cell's maximum power (Pₘₐₓ) point and dividing that value by a product of short circuit current (I_{sc}) and open circuit voltage (V_{oc}). Rₛ values were obtained from a slope of I-V curve at voltages around V_{oc}.

### Results

Series resistance (Rs) of solar cell electrodes on the positive layer and fill factor (FF) of the solar cells are shown in Table 2. Values are average of the samples fired between 825 and 885° C. peak set temperatures.

All of solar cell electrodes and solar cells except using glass frits #4, 5, 12, 13 and 15 showed series resistance (Rs) lower than 20 ohm and FF of 0.76 or higher.

TABLE 2
(mol %)

| | | | | | | Ts | Rs | |
|---|---|---|---|---|---|---|---|---|
| No. | PbO | SiO₂ | Al₂O₃ | B₂O₃ | Total | (° C.) | (ohm) | FF |
| 1 | 50.01 | 21.96 | 1.99 | 26.04 | 100.00 | 434 | 0.149 | 0.773 |
| 2 | 50.01 | 11.96 | 1.99 | 36.04 | 100.00 | 433 | 0.152 | 0.772 |
| 3 | 50.01 | 31.96 | 1.99 | 16.04 | 100.00 | 439 | 0.158 | 0.765 |
| 4 | 50.01 | 41.96 | 1.99 | 6.04 | 100.00 | 456 | 0.182 | 0.748 |
| 5 | 40.01 | 21.96 | 1.99 | 36.04 | 100.00 | 478 | 0.168 | 0.763 |
| 6 | 60.01 | 21.96 | 1.99 | 16.04 | 100.00 | 386 | 0.144 | 0.773 |
| 7 | 70.01 | 21.96 | 1.99 | 6.04 | 100.00 | 375 | 0.143 | 0.772 |
| 8 | 45.01 | 16.96 | 1.99 | 36.04 | 100.00 | 454 | 0.154 | 0.768 |
| 9 | 55.01 | 26.96 | 1.99 | 16.04 | 100.00 | 411 | 0.150 | 0.768 |
| 10 | 60.01 | 31.96 | 1.99 | 6.04 | 100.00 | 407 | 0.147 | 0.772 |
| 11 | 60.01 | 11.96 | 1.99 | 26.04 | 100.00 | 378 | 0.142 | 0.773 |
| 12 | 40.01 | 31.96 | 1.99 | 26.04 | 100.00 | 482 | 0.192 | 0.747 |
| 13 | 40.01 | 11.96 | 1.99 | 46.04 | 100.00 | 494 | 0.219 | 0.727 |
| 14 | 70.01 | 11.96 | 1.99 | 16.04 | 100.00 | 343 | 0.143 | 0.773 |
| 15 | 40.01 | 41.96 | 1.99 | 16.04 | 100.00 | 489 | 0.190 | 0.743 |
| 16 | 50.01 | 1.96 | 1.99 | 46.04 | 100.00 | 426 | 0.152 | 0.771 |
| 17 | 60.01 | 1.96 | 1.99 | 36.04 | 100.00 | 378 | 0.148 | 0.776 |
| 18 | 70.01 | 1.96 | 1.99 | 26.04 | 100.00 | 336 | 0.156 | 0.770 |
| 19 | 80.01 | 1.96 | 1.99 | 16.04 | 100.00 | 325 | 0.154 | 0.769 |
| 20 | 60.01 | 12.96 | 0.00 | 27.03 | 100.00 | 375 | 0.150 | 0.770 |
| 21 | 60.01 | 12.46 | 1.00 | 26.53 | 100.00 | 383 | 0.143 | 0.778 |
| 22 | 60.01 | 10.96 | 4.00 | 25.03 | 100.00 | 381 | 0.151 | 0.769 |
| 23 | 60.01 | 8.96 | 8.00 | 23.03 | 100.00 | 332 | 0.151 | 0.774 |

In turn, an effect of the conductive paste using the glass frit #11 was examined when it is applied on only the negative layer or both of the negative layer and the positive layer. Solar cell electrodes were prepared in the same manner as above except that the conductive paste is applied on both of the positive layer and the negative layer. FF was 0.775, while FF of the solar cell using the glass frit #11 only on the positive was 0.773 which was almost equal. Accordingly, the conductive paste of the present invention can be applied not only on the positive layer, but on the negative layer or even both layers.

What is claimed is:

1. A method of manufacturing a solar cell electrode comprising steps of:
(a) preparing a semiconductor substrate comprising a negative layer, a positive layer and passivation layers formed on the negative layer and the positive layer;
(b) applying a conductive paste onto the passivation layer(s) formed on the positive layer, on the negative layer, or on both of the positive layer and the negative layer,
wherein the conductive paste comprises;
(i) a conductive powder;
(ii) a glass frit comprising 45 to 81 mole percent (mol %) of PbO, 1 to 38 mol % of SiO₂ and 5 to 47 mol % of B₂O₃, based on the total molar fraction of each component in the glass frit; and
(iii) a resin binder; and
(c) firing the conductive paste.

2. The method of manufacturing a solar cell electrode of claim 1, wherein the glass frit further comprises 0 to 10 mol % of alumina (Al₂O₃), based on the total molar fraction of each component in the glass frit.

3. The method of manufacturing a solar cell electrode of claim 1, wherein the semiconductor substrate is an N-type base semiconductor substrate comprising a negative layer and a positive layer, wherein the positive layer is formed on one side of the negative layer.

4. The method of manufacturing a solar cell electrode of claim 3, the conductive paste is applied onto both the passivation layers formed on the positive layer and the negative layer.

5. The method of manufacturing a solar cell electrode of claim 3, wherein the conductive paste is applied on both of the positive layer and the negative layer.

6. The method of manufacturing a solar cell electrode of claim 1, wherein the conductive powder can comprise a metal selected from the group consisting of Fe, Al, Ni, Cu, Ag, Au, Mo, Mg, W, Co and Zn and a mixture thereof.

7. The method of manufacturing a solar cell electrode of claim 1, wherein particle diameter of the conductive powder is 0.1 to 10 μm.

8. A solar cell electrode manufactured by the method of claim 1.

9. A conductive paste for manufacturing a solar cell electrode comprising:
a conductive powder;
a glass frit comprising, 45 to 81 mole percent (mol %) of PbO, 1 to 38 mol % of SiO₂ and 5 to 47 mol % of B₂O₃, based on the total molar fraction of each component in the glass frit; and
a resin binder.

10. The conductive paste for manufacturing a solar cell electrode of claim 9, wherein the glass frit further comprises 0 to 10 mol % of alumina (Al₂O₃), based on the total molar fraction of each component in the glass frit.
